(19) United States
(12) Patent Application Publication
(10) Pub. No.: US 2024/0278288 A1
(43) Pub. Date: Aug. 22, 2024

(54) SUBSTRATE PROCESSING DEVICE

(71) Applicant: SCREEN Holdings Co., Ltd., Kyoto (JP)

(72) Inventors: Tomoyuki SHINOHARA, Kyoto-shi (JP); Kazuma FUNAHASHI, Kyoto-shi (JP)

(73) Assignee: SCREEN Holdings Co., Ltd., Kyoto (JP)

(21) Appl. No.: 18/581,337

(22) Filed: Feb. 19, 2024

(30) Foreign Application Priority Data
Feb. 22, 2023 (JP) 2023-026185

(51) Int. Cl. B08B 1/32; B08B 1/12; B08B 1/40; B08B 13/00

(52) U.S. Cl. CPC B08B 1/32; B08B 1/12; B08B 1/40; B08B 13/00

(57) ABSTRACT

A substrate processing device includes: a brush, cleaning a substrate held by a holding and rotating part; a brush holding part, detachably holding the brush; an arm, in which the brush holding part is provided at a tip end; a brush collection part, collecting the brush from the brush holding part; a brush installation part, storing an unused brush, and installing the unused brush that is stored to the brush holding part; and a brush movement mechanism (lifting mechanism and revolving driving part), moving the brush via an arm.

### CROSS-REFERENCE TO RELATED APPLICATION

This application claims the priority benefit of Japan application no. 2023-026185, filed on Feb. 22, 2023. The entirety of the above-mentioned patent application is hereby incorporated by reference herein and made a part of this specification.

### BACKGROUND

### Technical Field

The invention relates to a substrate processing device that processes a substrate. Examples of substrates include semiconductor substrates, substrates for flat panel displays (FPDs), glass substrates for photomasks, substrates for optical discs, substrates for magnetic discs, ceramic substrates, substrates for solar cells, etc. Examples of FPDs include liquid crystal displays, organic electroluminescence display devices, etc.

### Description of Related Art

A substrate processing device cleans a substrate by using a brush. The brush needs to be replaced periodically. The brush is generally replaced manually by the operator. However, there is an issue that the operating rate of the substrate processing device decreases and the productivity deteriorates due to brush replacement. Thus, devices able to automatically replace brushes have been proposed (see, for example, Patent Document 1).

Patent Document 1 discloses a scrubber cleaning device including a brush holding frame that holds multiple brushes. The brush holding frame is formed with multiple holding grooves. The scrubber cleaning device removes the brush from a brush head in an empty holding groove of the brush holding frame. The removed brush is held in the holding groove. Afterwards, the scrubber cleaning device moves another brush held by the brush holding frame to the lower side of the brush head, and installs the another brush to the brush head.

Patent Documents 2 and 3 disclose a brush cleaning device capable of selectively holding a desired brush among multiple brushes provided laterally in a standby pot.

### PRIOR ART DOCUMENT(S)

### Patent Document(s)

### [Patent Document 1]

Japanese Laid-open No. H08-318226

### [Patent Document 2]

Japanese Laid-open No. H08-010719

### [Patent Document 3]

Japanese Laid-open No. H10-223584

However, the conventional devices have issues as follows. For example, in Patent Document 1, the used brush that has been removed is held in the brush holding frame. In such case, the used brush and the unused brush are arranged laterally. In addition, it is possible for the brush holding frame to hold an unused brush after holding the used brush that has been removed. Thus, it is possible that particles of the used brush are attached to the unused brush.

The invention provides a substrate processing device capable of automatically replacing a brush while preventing particles from being installed to an unused brush.

### SUMMARY

A substrate processing device according to an aspect of the invention cleans a substrate by using a brush and includes: a substrate holding part, holding the substrate in a horizontal posture; a brush, cleaning the substrate held by the substrate holding part; a brush holding part, detachably holding the brush; an arm, in which the brush holding part is provided at a tip end; a brush collection part, collecting the brush from the brush holding part; a brush installation part, storing the brush, which is an unused brush, and installing the unused brush that is stored to the brush holding part; and a brush movement mechanism, moving, via the arm, the brush among a processing position on the substrate held by the substrate holding part, the brush collection part, and the brush installation part.

### BRIEF DESCRIPTION OF THE DRAWINGS

FIG. 1 is a side view illustrating a schematic configuration of a substrate processing device according to Embodiment 1.

FIG. 2 is a plan view illustrating the substrate processing device according to Embodiment 1.

FIG. 3A is a longitudinal cross-sectional view illustrating a brush and a brush holding part, and FIG. 3 B is a perspective view of the brush.

FIG. 4A is a lateral cross-sectional view illustrating a longitudinal recess and a recess provided in a cylindrically columnar part, FIG. 4B is a partial development view of a sidewall of the cylindrically columnar part, and FIG. 4C is a lateral cross-sectional view illustrating a state in which three steel balls are accommodated in the recess and the longitudinal recess.

FIG. 5 is a lateral cross-sectional view illustrating an effect of the longitudinal recess.

FIG. 6A is a plan view illustrating a removal member, and FIG. 6B is a front view of the removal member.

FIG. 7 is a longitudinal cross-sectional view illustrating a schematic configuration of a brush replacement part.

FIG. 8A is a longitudinal cross-sectional view illustrating a brush replacement part according to Embodiment 2, and FIG. 8B is a perspective view of the brush replacement part.

FIG. 9A is a side view illustrating a brush and a brush holding part according to Embodiment 3, and FIG. 9B is a perspective view of the brush holding part.

FIGS. 10A and 10B are lateral cross-sectional views of the brush and the brush holding part.

FIG. 11 is a plan view of a brush replacement part according to Embodiment 3.

FIG. 12 is a longitudinal cross-sectional view illustrating a schematic configuration of the brush replacement part according to Embodiment 3.

FIGS. 13A to 13C are longitudinal cross-sectional views for explaining brush replacement according to Embodiment 3.

FIG. 14 is a side view illustrating a removal member according to a modified example.

FIG. 15 is a longitudinal cross-sectional view illustrating a brush and a brush holding part according to a modified example.

FIG. 16 is a longitudinal cross-sectional view illustrating a brush and a brush holding part according to a modified example.

FIG. 17 is a longitudinal cross-sectional view illustrating a brush replacement part according to a modified example.

FIG. 18 is a plan view illustrating a substrate processing device according to a modified example.

### DESCRIPTION OF THE EMBODIMENTS

A substrate processing device according to an aspect of the invention cleans a substrate by using a brush and includes: a substrate holding part, holding the substrate in a horizontal posture; a brush, cleaning the substrate held by the substrate holding part; a brush holding part, detachably holding the brush; an arm, in which the brush holding part is provided at a tip end; a brush collection part, collecting the brush from the brush holding part; a brush installation part, storing the brush, which is an unused brush, and installing the unused brush that is stored to the brush holding part; and a brush movement mechanism, moving, via the arm, the brush among a processing position on the substrate held by the substrate holding part, the brush collection part, and the brush installation part.

According to substrate processing device of the invention, since the brush collection part and the brush installation part are separated, the used brush and the unused brush are not handled in the same region. Accordingly, the used brush that is removed can be handled in a state of being separated from the unused brush. Thus, the brush can be replaced automatically while preventing particles from being attached to the unused brush.

In addition, in the substrate processing device, it may also be that the brush installation part includes a brush accommodation container accommodating the unused brush in storage.

By including the brush accommodation container in the brush installation part, the brush installation part and the brush collection part can be separated. Thus, the particles due to the used brush can be reliably prevented from being attached to the unused brush handled by the brush installation part.

In addition, the substrate processing device may further include: a liquid supply part, supplying a liquid to the brush accommodation container. The brush accommodation container may immerse the unused brush into the liquid that is stored and store the unused brush.

When the unused brushes in storage are dried, for example, there is a possibility that particles enter fine gaps of the unused brushes. When particles enter such gaps, it takes a long time to remove the particles. Thus, after the unused brush is installed to the brush holding part, it may take a long time until brush cleaning is performed on the substrate that will become a product. Thus, the operating rate of the substrate processing device may decrease and the productivity may deteriorate. However, according to the invention, the liquid supply part supplies a liquid to the unused brushes in storage. Thus, the unused brushes in storage can be prevented from being dried. Thus, particles can be prevented from entering fine gaps of the unused brushes in storage.

In addition, in the substrate processing device, it may also be that the brush installation part further includes a horizontal movement part that horizontally moves the brush accommodation container.

Multiple unused brushes can be transported on the movement path RT when viewed in a plan view.

In addition, in the substrate processing device, it may also be that the brush collection part includes a brush collection container that collects the brush, which is a brush that has been used and removed.

By including the brush collection container in the brush collection part, the brush installation part and the brush collection part can be separated. Thus, the particles due to the used brush can be reliably prevented from being attached to the unused brush handled by the brush installation part.

In addition, in the substrate processing device, it may also be that the brush collection part includes a removal member for removing the brush.

With the removal member, the brush that has been used can be removed from the brush holding part, and such brush can be collected in the brush collection container.

In addition, in the substrate processing device, it may also be that the brush installation part is provided to be adjacent to the brush collection part.

After the used brush is removed by the brush collection part, the unused brush can be quickly installed. In addition, even in the state in which the brush installation part is adjacent to the brush collection part, the unused brush can be separated from the used brush that is removed.

In addition, the substrate processing device may further include: a separation part, provided between the brush collection part and the brush installation part and separating the brush collection part and the brush installation part.

By including the separation part between the brush collection part and the brush collection container, the brush installation part and the brush collection part can be separated. Thus, the particles due to the used brush can be prevented from being attached to the unused brush handled by the brush installation part.

In addition, in the substrate processing device, it may also be that the brush holding part includes: a hole part, formed in a cylindrically columnar shape along a central axis extending vertically; three opening parts, provided on a sidewall on an inner side of the hole part and provided about the central axis; three protrusion parts, respectively protruding from the three opening parts toward the hole part; and a biasing part, provided on an outer side of the three protrusion parts, and biasing the three protrusion parts in a direction of the central axis, the brush includes: a brush body, having a cleaning surface for cleaning the substrate; and a brush support part, supporting the brush body from a side opposite to the cleaning surface; a cylindrically columnar part, protruding from the brush support part toward the side opposite to the cleaning surface; and a recess and a longitudinal recess, provided on a sidewall of the cylindrically columnar part and about an axis of the cylindrically columnar part, wherein the longitudinal recess is recessed longitudinally in a circumferential direction; and in a case where the cylindrically columnar part is inserted into the hole part of the brush holding part, the recess accommodates one of the three protrusion parts, and the longitudinal recess accommodates at least one of remaining two protrusion parts.

The longitudinal recess is recessed longitudinally along the circumferential direction, and can accommodate two of the three steel balls. Thus, for example, when the cylindrically columnar part of the brush is inserted into the hole part of the brush holding part, one of the three steel balls is accommodated in the longitudinal recess. Thus, the movement of the brush with respect to the brush holding part in the upper-lower direction can be limited.

In addition, the substrate processing device may further include: a brush body, having a cleaning surface for cleaning the substrate; and a brush support part, supporting the brush body from a side opposite to the cleaning surface, the brush support part includes: a guide, extending in a horizontal direction set in advance on the side opposite to the cleaning surface; an opening part, provided at the guide; a protrusion part, protruding outward from the opening part; a button part, provided on an outer peripheral surface of the brush support part; and a protrusion width adjustment mechanism, adjusting a protrusion width of the protrusion part according to a pressing amount of the button part, the brush holding part includes: a guide holding part, holding the guide to be movable in the horizontal direction; and a recess, provided at the guide holding part to accommodate the protrusion part, in a case where the button part is pressed, the protrusion width adjustment mechanism makes the protrusion part retreat inwardly from the opening part, thereby allowing the brush to be able to move in the horizontal direction with respect to the brush holding part, and in a case where the button part is not pressed, the protrusion width adjustment mechanism makes the protrusion part protrude outward from the opening part, thereby allowing to accommodate the protrusion part in the recess and limit a movement of the brush in the horizontal direction.

The brush includes the guide extending in the horizontal direction set in advance. The brush holding part includes the guide holding part holding the guide to be movable in the horizontal direction. Thus, the movement of the brush in the upper-lower direction and the rotation direction with respect to the brush holding part can be limited. In addition, by accommodating the protrusion part in the recess, the movement in the horizontal direction can also be limited.

According to the substrate processing device according to the invention, it is possible to automatically replace brushes while preventing particles from being attached to an unused brush.

### Embodiment 1

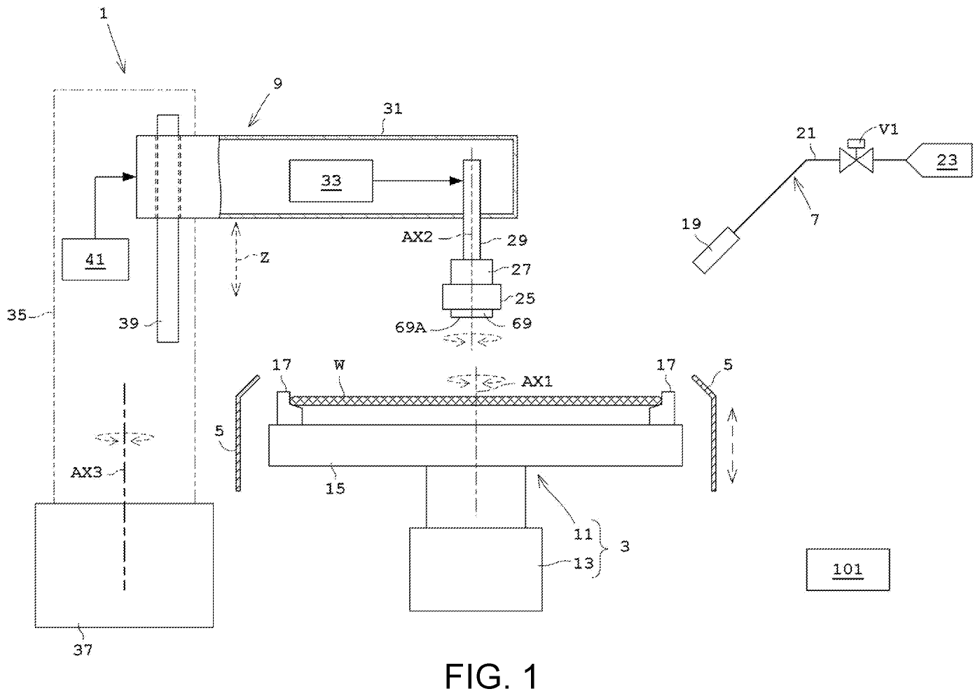

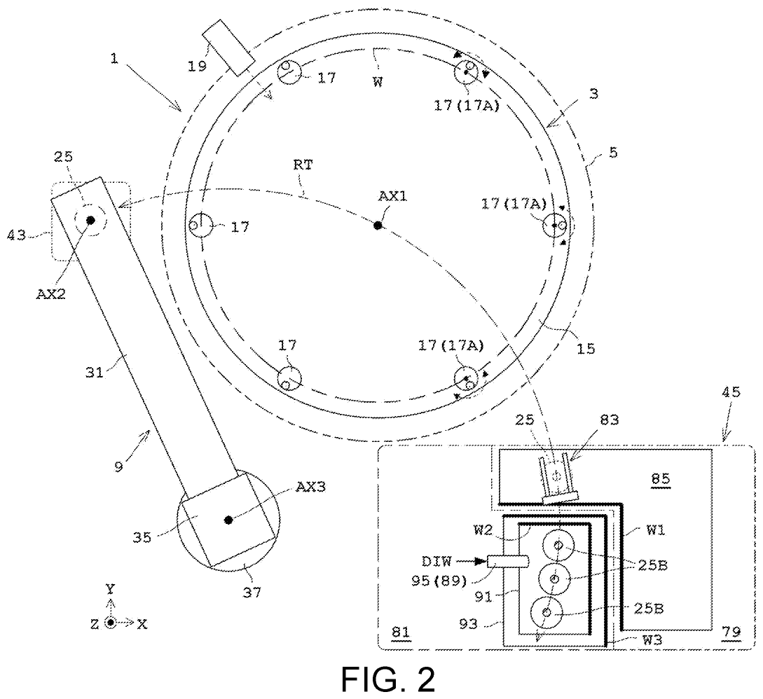

In the following, Embodiment 1 of the invention will be described with reference to the drawings. FIG. 1 is a side view illustrating a schematic configuration of a substrate processing device 1. FIG. 2 is a plan view illustrating the substrate processing device 1.

### (1) Basic Configuration of the Substrate Processing Device

Referring to FIGS. 1 and 2, the substrate processing device 1 cleans a substrate W by using a brush 25. The substrate processing device 1 includes a holding and rotating part 3, a cup 5, a processing liquid supply part 7, a rinse mechanism 9, and a control part 101. The holding and rotating part 3 is equivalent to the substrate holding part of the invention.

The holding and rotating part 3 holds the substrate W in a horizontal posture and rotates the substrate W about a vertical axis AX1. The substrate W is formed in a disc shape. The holding and rotating part 3 includes a spin chuck 11 and a rotation driving part 13. The rotation driving part 13 includes an electric motor. The rotation driving part 13 rotates the spin chuck 11 holding the substrate W about the vertical axis AX1.

As shown in FIG. 2, the spin chuck 11 includes a spin base 15 and three or more (six, for example) holding pins 17. The spin base 15 is formed in a disc shape. The vertical axis AX1 passes through the center of the spin base 15 (i.e., the substrate W). The six holding pins 17 are erected at equal intervals on an edge part of the upper surface of the spin base 15. In addition, among the six holding pins 17, each of three holding pins 17A provided on a side, for example, rotates about a vertical axis that passes through itself. Accordingly, the spin chuck 11 holds the substrate W by sandwiching the edge of the substrate W by using the six holding pins 17. In addition to being a mechanical chuck described herein, the spin chuck 11 may also be a vacuum chuck or an electrostatic chuck.

The cup 5 is formed to surround the outer periphery of the substrate W in the horizontal posture held by the holding and rotating part 3. The cup 5 receives a processing liquid scattered due to the rotation of the substrate W, for example. The cup 5 is configured to be able to be lifted and lowered.

The processing liquid supply part 7 includes a processing liquid nozzle 19, a processing liquid supply pipe 21, a processing liquid supply source 23, and an opening/closing valve V1. The cleaning liquid nozzle 19 discharges the processing liquid to the substrate W held by the holding and rotating part 3. As an example, pure water, such as deionized water (DIW), is used as the processing liquid. The processing liquid pipe 21 connects the processing liquid nozzle 19 and the processing liquid supply source 23. The processing liquid supply source 23 supplies the processing liquid to the processing liquid nozzle 19 via the processing liquid pipe 21. The opening/closing valve V1 is provided at the processing liquid pipe 21. The opening/closing valve V1 performs supply of the processing liquid and stops the supply.

The brush mechanism 9 includes the brush 25, the brush holding part 27, a shaft 29, an arm 31, and an electric motor 33. The brush 25 cleans the substrate W held by the holding and rotating part 3. The brush holding part 27 detachably holds the brush 25. The brush 25 and the brush holding part 27 will be described in detail in the following.

The upper end of the brush holding part 27 is fixed to the lower end of the shaft 29 extending in the vertical direction. The upper part of the shaft 29 is held to be rotatable about a vertical axis AX2 by using the arm 31 extending in a horizontal direction. The shaft 29 is rotated about the vertical axis AX2 by the electric motor 33 via a belt or a gear, for example. The brush 25, the brush holding part 27, and the shaft 29 are provided at a tip end (tip end side) of the arm 31.

The brush mechanism 9 further includes a lifting mechanism 35 and a revolving driving part 37. The lifting mechanism 35 lifts and lowers the brush 25, the brush holding part 27, and the arm 31, etc. The lifting mechanism 35 includes a guide rail 39 and a lifting driving part 41. The base end of the arm 31 is slidably contacted to be liftable by using the guide rail 39. The guide rail 39 guides the arm 31 in the upper-lower direction. The lifting driving part 41 includes an electric motor and a screw shaft, for example. The lifting driving part 41 may also be an air cylinder.

The revolving driving part 37 is provided on the outer side of the substrate W held by the rotating and holding part 3 and the cup 5. The revolving driving part 37 revolves the brush 25, the brush holding part 27, the arm 31, and the lifting mechanism 35, etc., about a vertical axis AX3. The revolving driving part 37 includes an electric motor. As shown in FIG. 2, the lifting mechanism 35 and the revolving driving part 37 moves the brush 25, via the arm 31, among a processing position on the substrate W held by the holding and rotating part 3, a standby pot 43, and a brush replacement part (a brush collection part 79 and a brush installation part 81). In addition, the lifting mechanism 35 and the revolving driving part 37 are equivalent to the brush movement mechanism of the invention.

### (2) Configuration for Installing/Uninstalling the Brush

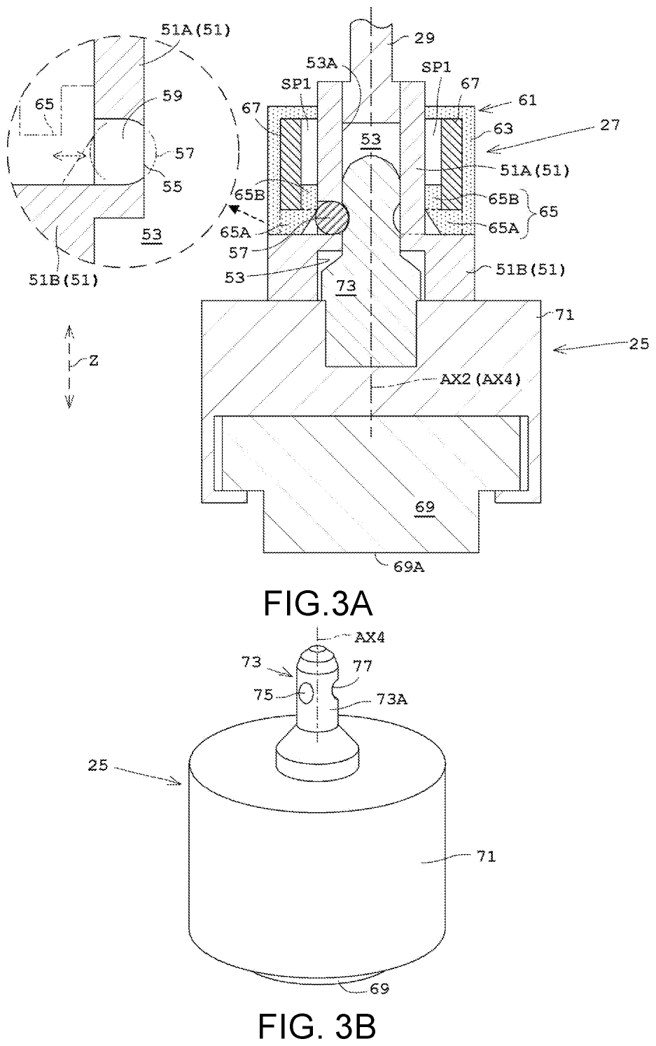

FIG. 3A is a longitudinal cross-sectional view illustrating the brush 25 and the brush holding part 27. FIG. 3B is a perspective view of the brush 25. The brush holding part 27 includes a cylindrical member 51, a hole part 53, three opening parts 55, three steel balls 57, ball accommodation parts 59, and a biasing part 61. The steel ball 57 is equivalent to the protrusion part of the invention.

The outer diameter of an upper part 51A of the cylindrical member 51 is smaller than the outer diameter of a lower part 51B of the cylindrical member 51. The hole part 53 is formed in a cylindrically columnar shape along the central axis (i.e., the vertical axis AX2) extending vertically. The lower end of the shaft 29 is linked to the upper end of the hole part 53. Accordingly, the cylindrical member 51 is fixed to the shaft 29.

The cylindrical member 51 is formed with three ball accommodation parts 59. The three ball accommodation parts 59 are provided at equal intervals (intervals of 120°) about the vertical axis. The ball accommodation part 59 has an opening part 55 on a sidewall 53A on the inner side of the hole part 53. The three steel balls 57 accommodated in the three ball accommodation parts 59 are configured so that portions of the steel balls 57 protrude from the opening parts 55

Although three ball accommodation parts 59 are provided in the configuration, there may also be four or more ball accommodation parts. In addition, although the steel ball 57 is formed by iron such as stainless steel, for example, other metals or resins may also be used. Although three steel balls 57 are provided, there may also be four or more steel balls 57.

The three steel balls 57 accommodated in the three ball accommodation parts 59 are supported by the biasing part 61. The biasing part 61 is provided to surround the outer periphery of the upper part 51A of the cylindrical member 51. The biasing part 61 includes a cylindrical case part 63, a pressing part 65, and a spring member (elastic member) 67 in a cylindrical shape. The spring member 67 may have a slit in the upper-lower direction, and a cross-sectional surface of the spring member 67 may be in a C shape. The inner wall of the upper end of the case part 63 is formed to achieve the outer wall of the upper part 51A of the cylindrical member 51. The lower end of the case part 63 is in contact with the upper surface of the lower part 51B of the cylindrical member 51. The case part 63 forms a space SP1 in which the spring member 67 is provided.

The pressing part 65 is integrally formed by an abutting part 65A and a limitation part 65B. When viewed in a plan view, the abutting part 65A is an annular-shaped member, and is tapered on the inner peripheral surface so that the cross-sectional area of a hollow part decreases from the lower side toward the upper side. In addition, the abutting part 65A is provided between the spring member 67 and the cylindrical member 51 in an upper-lower direction Z. When viewed in a plan view, the limitation part 65B is formed in an annular shape whose outer diameter is smaller than the abutting part 65A and whose inner diameter is the same as the abutting part 65A, and is formed to extend from the upper surface of the abutting part 65A. The spring member 67 is formed by using metal, such as stainless steel. The spring member 67 is provided between the case part 63 and the limitation part 65B in the horizontal direction. The inner peripheral surface of the abutting part 65A and the spring member 67 press the three steel balls 57 toward the inner peripheral side (the side of the three opening parts 55).

The brush 25 is detachable with respect to the brush holding part 27. As shown in FIG. 3B, the brush 25 includes a brush body 69, a brush support part 71, and a cylindrically columnar part 73. As an example, a polyvinyl alcohol (PVA) sponge brush is used as the brush body 69. The brush 69 is formed in a cylindrically columnar shape. The brush body 69 has a cleaning surface 69A for cleaning the substrate W. The brush support part 71 supports the brush body 69 from a side opposite to the cleaning surface 69A. The brush support part 71 is also formed in a cylindrically columnar shape. The cylindrically columnar part 73 extends from the brush support part 71 toward a side opposite to the cleaning surface 69A. The cylindrically columnar part 73 is fixed to the brush support part 71. On the outer peripheral surface 73A of the cylindrically columnar part 73, a recess 75 and a longitudinal recess 77 are formed. The longitudinal recess 77 is a recess longer than the recess 75 in the circumferential direction of the cylindrically columnar part 73.

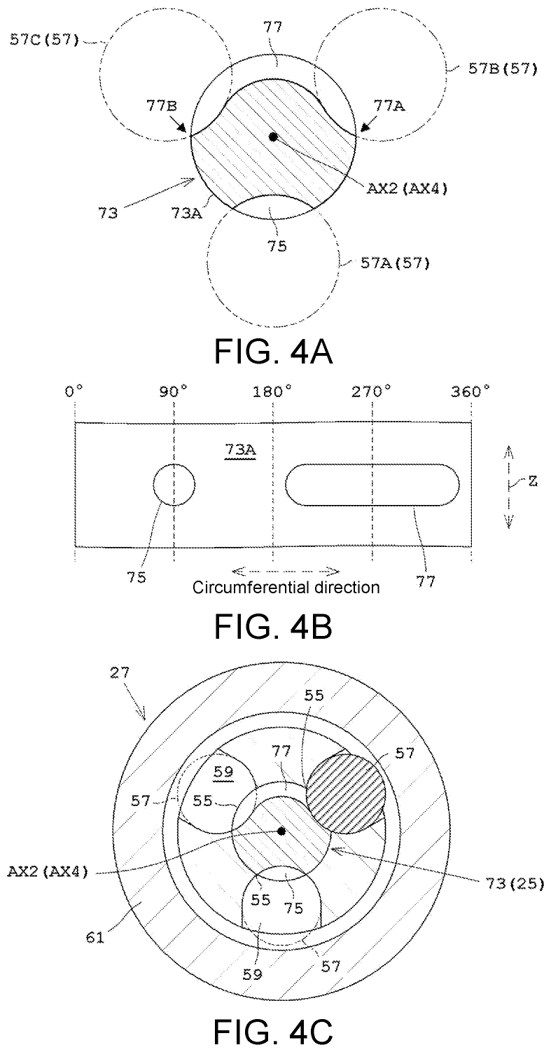

FIG. 4A is a lateral cross-sectional view illustrating the longitudinal recess 77 and the recess 75 provided in the cylindrically columnar part. FIG. 4B is a partial development view of the sidewall (outer peripheral surface) 73A of the cylindrically columnar part 73. FIG. 4C is a lateral cross-sectional view illustrating a state in which three steel balls 57 are accommodated in the recess 75 and the longitudinal recess 77.

The length of the recess 75 in the upper-lower direction Z and the width of the recess 75 in the horizontal direction are formed to be substantially the same as the length (in the upper-lower direction Z) and the width (horizontal direction) of substantially hemispherical portions of the steel balls 57 partially protruding from the opening parts 55. In addition, the length of the longitudinal recess 77 in the upper-lower direction Z is also formed to be substantially the same as the length (in the upper-lower direction Z) of the substantially hemispherical portions of the steel balls 57 partially protruding from the opening parts 55.

As shown in FIG. 4B, the longitudinal recess 77 is longitudinally recessed in the circumferential direction. As shown in FIGS. 4A and 4B, in the case where the cylindrically columnar part 73 of the brush 25 is inserted into the hole part 53 of the brush holding part 27, the recess 75 accommodates a first steel ball 57A among the three steel balls 57. In addition, the longitudinal recess 77 accommodates the remaining two steel balls 57B, 57C at the two ends thereof. In the case where the cylindrically columnar part 73 is hollow (in a cylindrical shape), the recess 77 and the longitudinal recess 77 may also be penetrating hole parts.

By accommodating the three steel balls 57 in the recess 75 and the longitudinal recess 77, the movements of the brush 25 with respect to the brush holding part 27 in the upper-lower direction and the circumferential direction are limited. The limitation of the movement in the circumferential direction is not only exerted by accommodating the first steel ball 57A in the recess 75, but is also exerted by accommodating the two steel balls 57B, 57C in the longitudinal recess 77. In FIG. 4A, in the case where the steel balls 57B, 57C rotate about the vertical axis AX2, the clockwise rotation of the second steel ball 57B is limited by a first end 77A of the longitudinal recess 77, and the counterclockwise rotation of the third steel ball 57C is limited by the second end 77B.

At the time of inserting the cylindrically columnar part 73 of the brush 25 into the hole part 53 of the brush holding part 27, with each steel ball 57 being pressed by the cylindrically columnar part 73 toward the outer peripheral side, the steel ball 57 does not protrude from the opening part 55 toward the side of the hole part 53. Specifically, the pressing part 65 is supported in a state of being movable in the vertical direction by using the spring member 67. When viewed in a plan view, the abutting part 65A of the pressing part 65 has a taper shape on the inner peripheral surface. In the taper shape, the cross-sectional area of the hollow part decreases from the lower surface toward the upper surface when viewed in a plan view. Thus, when the inner peripheral surface is pushed outward by the steel balls 57, the orientation (horizontal direction) of the pushing force is converted into an upward orientation in the vertical direction. Thus, with the pressing part 65 moving upward in the vertical direction, the steel balls 57 are accommodated on the inner side with respect to the sidewall 53A of the cylindrical member 51. Then, when the three opening parts 55 and the two recesses 75, 77 face each other, through the restoring force of the pressing part 65 and the spring member 67, the three steel balls 57 partially protrude from the three opening parts 55. Specifically, the downward force (vertical direction) generated by the pressing part 65 is converted into a force (horizontal direction) from the inner peripheral surface toward the inner side by the taper-shaped inner peripheral surface. Accordingly, by partially protruding from the respective opening parts 55, the three steel balls 57 biased by the inner peripheral surface in the taper shape are accommodated in the recess 75 and the longitudinal recess 77, and the movement of the brush 25 is limited.

In addition, in FIG. 3A, when the brush 25 is removed from the brush holding part 27, the brush 25 is pulled downward. With a predetermined pulling force, the cylindrically columnar part 73 presses the three steel balls 57 outward. Accordingly, the three steel balls 57 do not protrude from the opening parts 55 toward the side of the hole part 53. Thus, the brush 25 can be removed from the brush holding part 27.

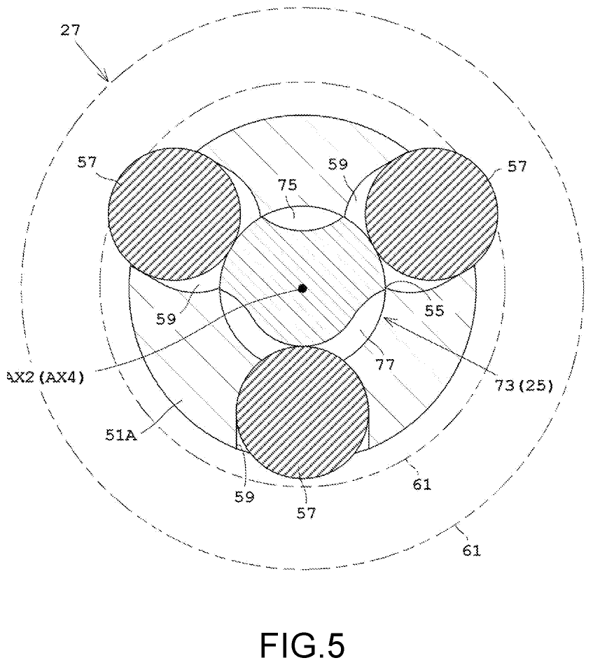

Here, the effect of the longitudinal recess 77 is described with reference to FIG. 5. For example, it is assumed that the longitudinal recess 77 is not provided in the cylindrically columnar part 73, and “three recesses 75” corresponding to the three steel balls 57 are provided about a vertical axis AX4 at intervals of 120°. In such case, when the brush 25 is installed to the brush holding part 27, it is difficult to accommodate the three steel balls 57 in the three recesses 75. At the time of inserting the cylindrically columnar part 73 of the brush 25 into the hole part 53 of the brush holding part 27, if the three steel balls 57 are not accommodated in the three recesses 75, the cylindrically columnar part 73 may fall off from the hole part 53.

Comparatively, in the cylindrically columnar part 73 of the embodiment, the recess 75 and the longitudinal recess 77 are provided. As shown in FIG. 5, at the time of inserting the cylindrically columnar part 73 of the brush 25 into the hole part 53 of the brush holding part 27, at least one steel ball 57 is accommodated in the longitudinal recess 77. Thus, the movement of the brush 25 in the upper-lower direction is limited. Thus, the cylindrically columnar part 73 can be prevented from falling off from the hole part 53. Then, for example, through the rotation of the brush 25 about the vertical axis AX2, the brush 25 slides in the circumferential direction with respect to the brush holding part 27. Accordingly, the three steel balls 57 are accommodated in the recess 75 and the longitudinal recess 77, and the rotation of the brush 25 is limited. In addition, the brush 25 can be reliably held.

### (3) Configuration of the Brush Replacement Part

Referring to FIG. 2, the brush replacement part 45 is provided to replace a used brush 25A (brush 25) with an unused brush 25B. The unused brush 25B is configured to be the same as the brush 25. For example, like the brush body 69 of the brush 25, the brush body 69 of the unused brush 25B is a PVA sponge brush. The standby pot 43 is provided on the outer side of the cup 5 provided on the periphery of the holding and rotating part 3.

When viewed in a plan view, the brush replacement part 45 is provided on a side opposite to the standby pot 43 via the substrate W held by the holding and rotating part 3 and the cup 5. In addition, the brush replacement part 45 is provided at a position on the outer side of the cup 5 and the substrate W held by the holding and rotating part 3. The brush replacement part 45 includes the brush collection part 79 and the brush installation part 81.

### (3-1) Brush Collection Part

In the brush collection part 79, the brush 25 is removed from the brush holding part 27. The brush collection part 79 includes a removal member 83 and a brush collection container 85. The removal member 83 is provided above the brush collection container 85. When viewed in a plan view, the removal member 83 is provided on a path RT of the horizontal movement of the brush 25 by using the brush mechanism 9.

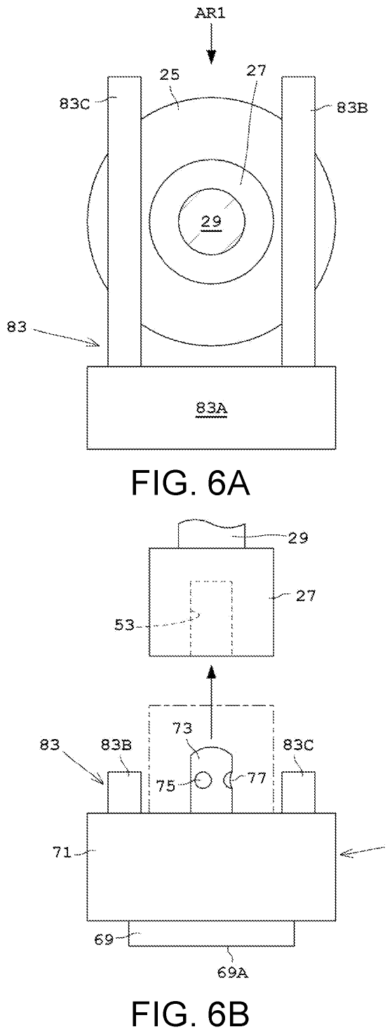

FIG. 6A is a plan view illustrating the removal member 83. FIG. 6B is a front view of the removal member 83 when viewed in a direction indicated by an arrow sign AR1 of FIG. 6A. The removal member 83 is a member for limiting the position (action) of the brush 25 in the height direction by abutting against the upper surface of the brush 25 at the time of removing the brush 25. As shown in FIG. 6A, the removal member 83 has one foundation portion 83A and two hook portions 83B, 83C separated from the foundation portion 83A, and is formed in a U shape or a forked shape.

When the brush 25 is removed from the brush holding part 27, the brush mechanism 9 firstly makes the brush holding part 27 pass through between the two hook portions 83B, 83C. Then, the brush mechanism 9 lifts the brush holding part 27. As shown in FIG. 6B, in this way, the brush 25 is prevented from moving upward by the two hook portions 83B, 83C, and the brush holding part 27 is separated from the brush 25 while being lifted. Thus, the brush 25 is removed from the brush holding part 27. The removed brush 25 is not held by the removal member 83 (the hook portions 83B, 83C). Thus, the brush 25 is dropped from the removal position and collected in the brush collection container 85.

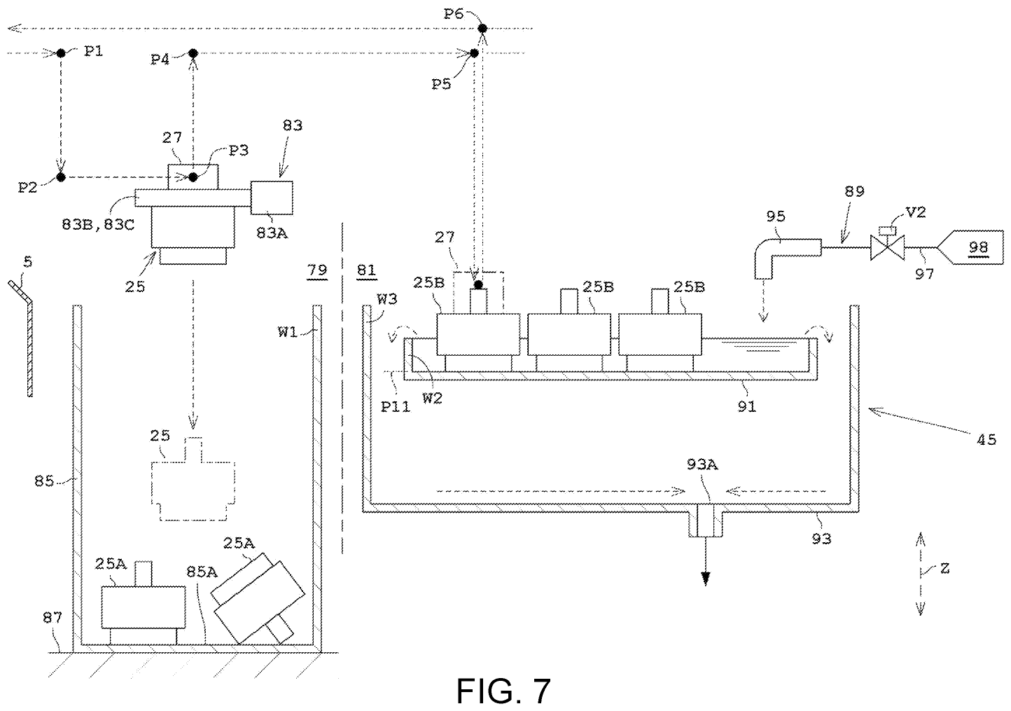

FIG. 7 is a longitudinal cross-sectional view illustrating a schematic configuration of the brush replacement part 45. The brush collection container 85 collects the used brush 25A at a position lower than a storage position (height) P11 of the unused brush 25B. That is, a bottom surface 85A on the inner side of the brush collection container 85 is provided at a position lower than the storage position P11. Also, the brush collection container 85 is provided below the two hook portions 83B, 83C of the removal member 83. The brush collection container 85 is detachable with respect to a base 87 of the substrate processing device 1. Thus, the brush collection container 85 can be carried in a state in which the used brush 25A is accommodated.

### (3-2) Brush Installation Part

Referring to FIG. 2, the brush installation part 81 installs the unused brush 25B to the brush holding part 27. The brush installation part 81 is provided in adjacency with the brush collection part 79. The brush installation part 81 is provided at a position different from the brush collection part 79.

Referring to FIG. 7, the brush installation part 81 stores one or multiple (e.g., 3) unused brushes 25B. The brush installation part 81 includes a brush accommodation container 91 and a liquid discharge container 93. In addition, a liquid supply part 89 supplies a liquid to the brush accommodation container 91.

The liquid supply part 89 includes a liquid nozzle 95, a liquid pipe 97, a liquid supply source 98, and an opening/closing valve V2. The liquid nozzle 95 supplies pure water, such as deionized water (DIW), as the liquid, to the brush accommodation container 91. The pure water from the liquid nozzle 95 may or may not be directly applied to the unused brush 25B. The liquid supply source 98 supplies pure water to the liquid nozzle 95 through the liquid pipe 97. The opening/closing valve V2 is provided at the liquid pipe 97. The opening/closing valve V2 performs supply of the pure water and stops the supply.

The brush accommodation container 91 stores the pure water supplied from the liquid nozzle 95 of the liquid supply part 89. The brush accommodation container 91 accommodates three unused brushes 25B in storage while immersing the brush bodies 69 of the three unused brushes 25B into pure water that is stored. The bottom of the brush accommodation container 91 is formed in a shallow tray shape, for example. At the time of storing the unused brushes 25B, the brush accommodation container 91 is continuously supplied with pure water from the liquid nozzle 95. Accordingly, the cleanliness of the pure water in which the unused brushes 25B are immersed can be maintained. A sidewall W1 facing the brush installation part 81 among the sidewalls of the brush collection container 85 and a sidewall W2 facing the brush collection part 79 in the brush accommodation container 91 are equivalent to the separation part of the invention. According to the configuration, the brush collection part 79 and the brush installation part 81 can be separated. Thus, the particles due to the used brush 25A can be reliably prevented from being attached to the unused brush 25B handled by the brush installation part 81.

The liquid discharge container 93 accommodates the brush accommodation container 91. That is, the outer periphery of the side of the brush accommodation container 91 is surrounded by the inner wall of the liquid discharge container 93. A discharge port 93A is provided at the bottom of the liquid discharge container 93. Thus, the liquid discharge container 93 receives the pure water overflown from the upper opening part of the brush accommodation container 91 while discharging pure water. A sidewall W3 facing the brush collection part 79 of the liquid discharge container 93 is equivalent to the separation part of the invention. That is, at least one of the sidewalls W1, W2, W3 is equivalent to the separation part of the invention.

As shown in FIG. 2, when viewed in the plan view, the three unused brushes 25B, for example, are provided on a movement path RT of the brush holding part 27. In the brush accommodation container 91, a guide, such as a recess, is provided, for example, so as to store each of the unused brushes 25B at a position set in advance.

### (4) Control Part of the Substrate Processing Device

The substrate processing device 1 includes a control part 101 and a storage part (not shown). The control part 101 controls the processing of the substrate W and brush replacement. The control part 101 includes one or more processors, such as a central processing unit (CPU). The storage part includes at least one of a read-only memory (ROM), a random access memory (RAM), and a hard disk, for example. The storage part stores a computer program necessary for the control part 101 to control the respective components of the substrate processing device 1.

### (5) Operation of the Substrate Processing Device

In the following, the operation of the substrate processing device 1 is described. As shown in FIG. 2, normally, the brush 25 held by the brush holding part 27 standbys in the standby pot 43. Firstly, the normal brush cleaning of the back surface of the substrate W is described.

### (5-1) Normal Brush Cleaning of the Back Surface of the Substrate W

A transport robot not shown herein transports the substrate W onto the spin chuck 11 of the holding and rotating part 3. A device surface (front surface) in which an electronic circuit of the transported substrate W is formed faces downward, and a non-device surface (back surface) of the substrate W faces upward. The holding and rotating part 3 holds the substrate W that is transported, and rotates the substrate W about the vertical axis AX1. When the opening/closing valve V1 is opened, the processing liquid is discharged from the processing liquid nozzle 19 to the back surface (i.e., the upper surface) of the substrate W. Then, the brush mechanism 9 rotates the brush 25 about the vertical axis AX2, while swinging the brush 25 about the vertical axis AX3 and applying the brush 25 on the back surface of the substrate W on which the processing liquid is discharged, thereby cleaning the back surface of the substrate W.

After the cleaning of the back surface of the substrate W, the brush mechanism 9 returns the brush 25 to the standby pot 43, and stops discharging the processing liquid by closing the opening/closing valve V1. After the discharge of the processing liquid is stopped, the holding and rotating part 3 dries the substrate W by rotating the substrate W at a high speed. Then, the holding and rotating part 3 stops the rotation of the substrate W and releases the holding of the substrate W. Then, the transport robot not shown herein transports the substrate W cleaned by the brush 25 from the spin chuck 11.

### (5-2) Brush Replacement

In the following, brush replacement is described. The brush mechanism 9 moves the brush holding part 27 holding the brush 25 from the standby pot 43 to the position P1 (see FIG. 7) on the outer side of the cup 5. Then, the lifting mechanism 35 of the brush mechanism 9 lowers the brush holding part 27 from the position P1 to a position P2. Then, the revolving driving part 37 of the brush mechanism 9 revolves the brush holding part 27 about the vertical axis AX3 from the position P2 to a position P3. Accordingly, the brush holding part 27 is moved to between the two hook portions 83B, 83C of the removal member 83 of the brush collection part 79.

Then, the lifting mechanism 35 lifts the brush holding part 27 from the position P3 to a position P4. At this time, the upward movement of the brush 25 is limited by the two hook portions 83B, 83C. Thus, only the brush holding part 27 is lifted to the position P4, and the brush 25 is removed from the brush holding part 27. The removed brush 25 is dropped from a position of removal performed by the removal member 83 to be collected as the used brush 25A in the brush collection container 85.

Then, the revolving driving part 37 revolves the brush holding part 27 about the vertical axis AX3 from the position P4 to a position P5. The position P5 is a position above one of the three unused brushes 25B stored in the brush accommodation container 91. After the brush holding part 27 is moved to the position P5, the lifting mechanism 35 lowers the brush holding part 27. Accordingly, the cylindrically columnar part 73 of the unused brush 25B is inserted into the hole part 53 of the brush holding part 27. In addition, by accommodating the three steel balls 57 in the recess 75 and the longitudinal recess 75 provided in the cylindrically columnar part 73, the unused brush 25B is fixed in the upper-lower direction and the rotation direction (the rotation direction about the vertical axis AX2) with respect to the brush holding part 27.

Then, the lifting mechanism 35 lifts the brush holding part 27 holding the unused brush 25B to a position P6. Then, the brush mechanism 9 moves the unused brush 25B from the position P6 to the standby pot 43, for example. The unused brush 25B performs brush cleaning on the back surface of the substrate W after a process of removing initial contamination to improve cleanliness.

According to the embodiment, since the brush collection part 79 and the brush installation part 81 are separated, the used brush 25A and the unused brush 25B are not handled in the same region. Accordingly, the unused brush 25B can be separated from the used brush 25A that is removed. Thus, the brush 25 can be replaced automatically while preventing particles from being attached to the unused brush 25B.

In addition, the brush installation part 81 includes the brush accommodation container 91 accommodating the unused brushes 25B in storage.

By including the brush accommodation container 91 in the brush installation part 81, the brush installation part 81 and the brush collection part 79 can be separated. Thus, the particles due to the used brush 25A can be reliably prevented from being attached to the unused brush 25B handled by the brush installation part 81.

In addition, the brush installation part 81 includes the liquid supply part 89 supplying pure water to the unused brushes 25B in storage.

When the unused brushes 25B in storage are dried, for example, there is a possibility that particles enter fine gaps of the unused brushes 25B. When particles enter such gaps, it is difficult to remove the particles. Thus, after the unused brush 25B is installed to the brush holding part 27, it may take a long time until brush cleaning is performed on the substrate W that will become a product. Thus, the operating rate of the substrate processing device 1 may decrease and the productivity may deteriorate. However, according to the embodiment, the liquid supply part 89 supplies pure water to the unused brushes 25B in storage. Thus, the unused brushes 25B in storage can be prevented from being dried. Thus, particles can be prevented from entering fine gaps of the unused brushes 25B in storage.

In addition, the brush collection part 79 includes the brush collection container 85 collecting the used brush 25A that is removed.

By including the brush collection container 85 in the brush collection part 79, the brush installation part 81 and the brush collection part 79 can be separated. Thus, the particles due to the used brush 25A can be reliably prevented from being attached to the unused brush 25B handled by the brush installation part 81.

In addition, the brush collection part 79 includes the removal member 83 for removing the brush 25.

By using the removal member 83, the brush 25 can be removed from the brush holding part 27 and collected as the used brush 25A in the brush collection container 85.

In addition, the brush installation part 81 is provided in adjacency with the brush collection part 79.

After the used brush 25A is removed by the brush collection part 79, the unused brush 25B can be quickly installed. In addition, even in the state in which the brush installation part 81 is adjacent to the brush collection part 79, the unused brush 25B can be separated from the used brush 25A that is removed.

In addition, between the brush collection part 79 and the brush installation part 81, the sidewall W1 of the brush collection container 85, the sidewall W2 of the brush accommodation container 91, or the sidewall W3 of the liquid discharge container 93 that separates the brush collection part 79 and the brush installation part 81 is provided. According to the configuration, the brush collection part 79 and the brush installation part 81 can be separated. Thus, the particles due to the used brush 25A can be reliably prevented from being attached to the unused brush 25B handled by the brush installation part 81.

In addition, the longitudinal recess 77 is recessed longitudinally along the circumferential direction, and can accommodate two of the three steel balls 57. Thus, for example, when the cylindrically columnar part 73 of the brush 25 is inserted into the hole part 53 of the brush holding part 27, one of the three steel balls 57 is accommodated in the longitudinal recess 77. Thus, the movement of the brush 25 with respect to the brush holding part 27 in the upper-lower direction can be limited. Thus, the brush 25 can be prevented from falling off from the brush holding part 27.

### Embodiment 2

Then, Embodiment 2 of the invention will be described with reference to the drawings. The description repeating that of Embodiment 1 will be omitted. In Embodiment 1, the position of the unused brush 25B that is stored is constant. That is, the position of the brush accommodation container 91 accommodating the unused brushes 25B is fixed. Regarding this point, it may also be configured that the brush accommodation container 91 is moved in X direction of FIG. 2.

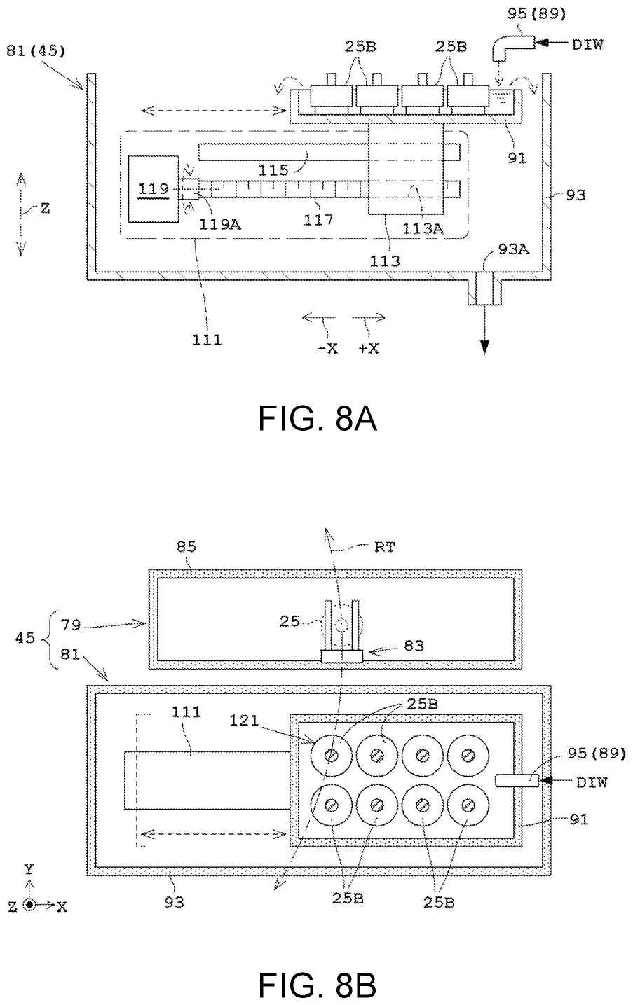

FIG. 8A is a longitudinal cross-sectional view illustrating the brush replacement part 45 according to Embodiment 2. FIG. 8B is a plan view of the brush replacement part 45. The brush installation part 81 further includes a horizontal movement part 11 horizontally moving the brush accommodation container 91 in X direction. The horizontal movement part 111, for example, is installed to the inner wall of the liquid discharge container 93.

The horizontal movement part 111 includes a slider 113, a guide rail 115, a screw shaft 117, and an electric motor 119. The slider 113, for example, is fixed to the lower surface of the brush accommodation container 91. Each of the guide rail 115 and the screw shaft 117 is provided to extend in X direction. The guide rail 115 penetrates through the slider 113. The screw shaft 117 is meshed with an internal thread 113A of the slider 113. An output shaft 119A of the electric motor 119 is linked with an end of the screw shaft 117. When the electric motor 119 rotates the screw shaft 117 in a forward direction, the slider 113 and the brush accommodation container 91 advance in +X direction. When the electric motor 119 rotates the screw shaft 117 in a backward direction, the slider 113 and the brush accommodation container 91 retreat in −X direction.

In FIG. 8B, in the case where brush replacement is performed by using the unused brush 25B indicated by a symbol 121, for example, the horizontal movement part 111 moves the brush accommodation container 91 in X direction to move the unused brush 25B indicated by the symbol 121 to a position overlapped with the movement path RT when viewed in a plan view. In addition, the brush mechanism 9 moves the brush holding part 27 in which the brush 25 is removed to the top of the unused brush 25B indicated by the symbol 121. Then, the brush mechanism 9 installs the unused brush 25B to the brush holding part 27 by lowering the brush holding part 27.

According to the embodiment, the brush installation part 81 further includes the horizontal movement part 11 horizontally moving the brush accommodation container 91. Any unused brush 25B can be transported on the movement path RT when viewed in a plan view. Thus, several unused brushes 25B can be accommodated and stored in the brush accommodation container 91.

In the embodiment, the horizontal movement part 111 moves the brush accommodation container 91 horizontally without horizontally moving the liquid discharge container 93. Regarding this point, it may also be that the horizontal movement part 111 integrally moves the brush accommodation container 91 and the liquid discharge container 93 horizontally.

### Embodiment 3

Then, Embodiment 3 of the invention will be described with reference to the drawings. The description repeating that of Embodiments 1 and 2 will be omitted. In Embodiments 1 and 2, brush replacement is performed by vertically moving the brush holding part 27 with respect to the brush 25 (the unused brush 25B). Regarding this point, brush replacement may also be performed by laterally moving a brush holding part 127 with respect to a brush 125 (an unused brush 125B).

### (6) Configuration for Installing/Uninstalling the Brush

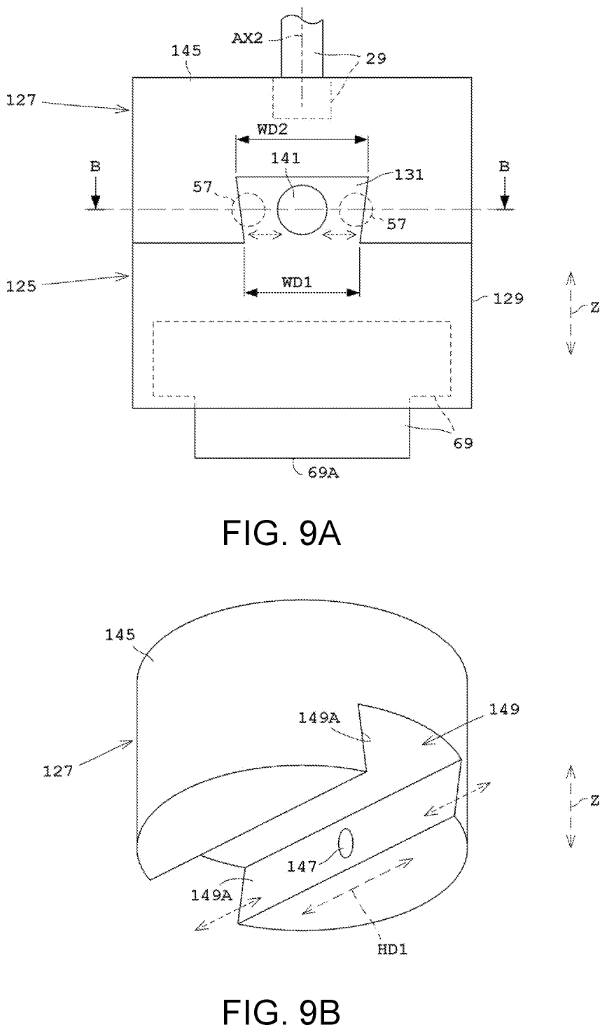

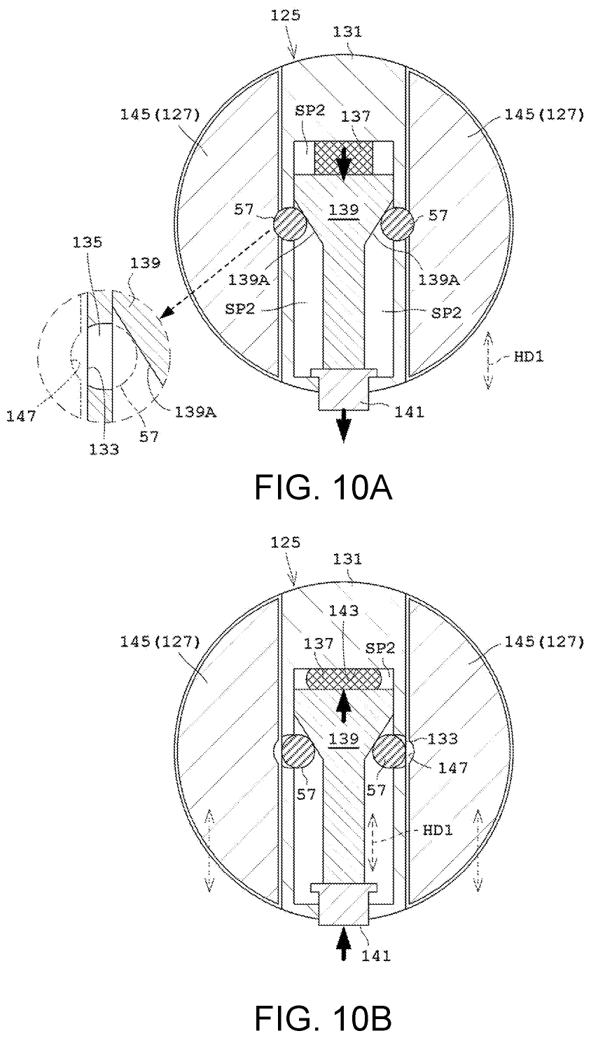

FIG. 9A is a side view illustrating the brush 125 and the brush holding part 127. FIG. 9B is a perspective view of the brush holding part 127. FIGS. 10A and 10B are lateral cross-sectional views of the brush 125 and the brush holding part 127 when viewed as indicated by an arrow sign B of FIG. 9A. In addition, FIG. 10A is a view illustrating an operation when a button 141 is not pressed. FIG. 10B is a view illustrating an operation when the button 141 is pressed.

Referring to FIGS. 9A and 10A, the brush 125 is detachable with respect to the brush holding part 127. The brush 125 includes the brush body 69, a brush support part 129, a guide 131, two opening parts 133, two steel balls 57, a space SP2, a ball accommodation part 135, an elastic member 137, a cam 139, and the button 141.

The brush support part 129 supports the brush body 69 from a side opposite to the cleaning surface 69A. The guide 131 is provided on a surface (upper surface) of the brush support part 129 on a side opposite to the cleaning surface 69A. The guide 131 is a member protruding upward from the upper surface of the brush support part 129. The guide 131 is formed in an elongated shape in a horizontal direction HD1 set in advance.

Referring to FIG. 10A, the guide 131 includes the space SP2 therein. The ball accommodation parts 135 are formed on two side surfaces parallel to the horizontal direction HD1 on the guide 131. On side surfaces on outer sides of the guide 131, the opening parts 133 are formed at portions facing the ball accommodation parts 135. Two steel balls 57 are accommodated in the two ball accommodation parts 135. The two steel balls 57 accommodated in the two ball accommodation parts 135 are supported by the elastic member 137 via the cam 139. Accordingly, the two steel balls 57 respectively partially protrude outward from the two opening parts 133.

The button 141 is provided on the outer peripheral surface (outer side wall) of the brush support part 129. That is, the button 141 is provided to protrude from the space SP2 toward the outer peripheral surface of the brush support part 129. The button 141 is also supported by the elastic member 137 via the cam 139. The elastic member 137 is supported by an inner wall 143 on the inner side of the space SP2. The elastic member 137 is, for example, a spring.

The cam 139 is provided to be sandwiched by the button 141 and the elastic member 137 in the space SP2. The cam 139 and the button 141 are movable along the horizontal direction HD1 in which the guide 131 extends. The cam 139 includes two inclined surfaces 139A. When viewed in a plan view, the two inclined surfaces 139A are formed on side surfaces of two sides orthogonal to the movement direction of the cam 139. When viewed in a plan view, the two inclined surfaces 139A are formed so that the cam 139 becomes thicker on the side of the elastic member 137. The two inclined surfaces 139A contact the two steel balls 57.

Referring to FIG. 9B, the brush holding part 127 includes a guide holding part 145 and two recesses 147. The guide holding part 145 holds the guide 131 to be movable in the horizontal direction HD1 in which the guide 131 extends. On the lower surface of the guide holding part 145, a groove part 149 extending linearly in the horizontal direction is provided. On two sidewalls 149A of the groove part 149, two recesses 147 are respectively provided. That is, the two recesses 147 are provided at the guide holding part 145 to accommodate the two steel balls 57. The two recesses 147 are provided to face each other. The length of the recess 147 in the upper-lower direction Z and the width of the recess 147 in the horizontal direction are formed similarly with those of the recess 75.

The groove part 149 is formed like a dovetail groove, for example. Thus, a width WD1 of the lower end of the groove part 149 is shorter than a width WD2 of the upper end of the groove part 149 (width WD1<width WD2). The guide 131 of the brush support part 129 is formed to fit the shape of the groove part 149. Thus, the guide 131 can enter from the two ends of the groove part 149 in the longitudinal direction.

When the guide 131 is accommodated in the groove part 149, the movement of the brush 125 (the guide 131) with respect to the brush holding part 127 (the groove part 149) in the upper-lower direction and the rotation direction is limited. However, the guide 131 can move along the longitudinal direction of the groove part 149. Thus, with the two steel balls 57 being accommodated in the two recesses 147 of the groove part 149, the horizontal movement of the guide 131 with respect to the groove part 149 is limited.

Then, the operation of the brush 125 is described. Referring to FIG. 10B, in the case where the button 141 is pressed, the cam 139 is moved toward the side of the elastic member 137. Thus, the button 141 elastically deforms the elastic member 137 via the cam 139. In addition, together with the movement of the cam 139, the two inclined surfaces 139A are also moved toward the side of the elastic member 137. Thus, the force pressing the two steel balls 57 outward from the two opening parts 133 is released. Thus, the two steel balls 57 can retreat inward (the side of the space SP2) from the opening parts 133. Accordingly, the brush 125 is movable with respect to the brush holding part 127 in the horizontal direction HD1.

Referring to FIG. 10A, in the case where the button 141 is not pressed, the cam 139 is moved toward the side of the button 141 through the restoring force of the elastic member 137. Together with the movement of the cam 139, the two inclined surfaces 139A are also moved toward the side of the button 141. Thus, the two inclined surfaces 139A press the two steel balls 57 outward from the two opening parts 133. That is, the restoring force of the elastic member 137 makes the two steel balls 57 partially protrude outward from the two opening parts 133. Accordingly, the two steel balls 57 are accommodated in the two recesses 147, and the movement of the brush 125 in the horizontal direction HD1 can be limited. In the configuration, the elastic member 137 and the cam 139 are equivalent to the protrusion width adjustment mechanism of the invention adjusting the protrusion width (protrusion amount) of the protrusion part according to the pressing amount of the button part.

### (7) Configuration of the Brush Replacement Part

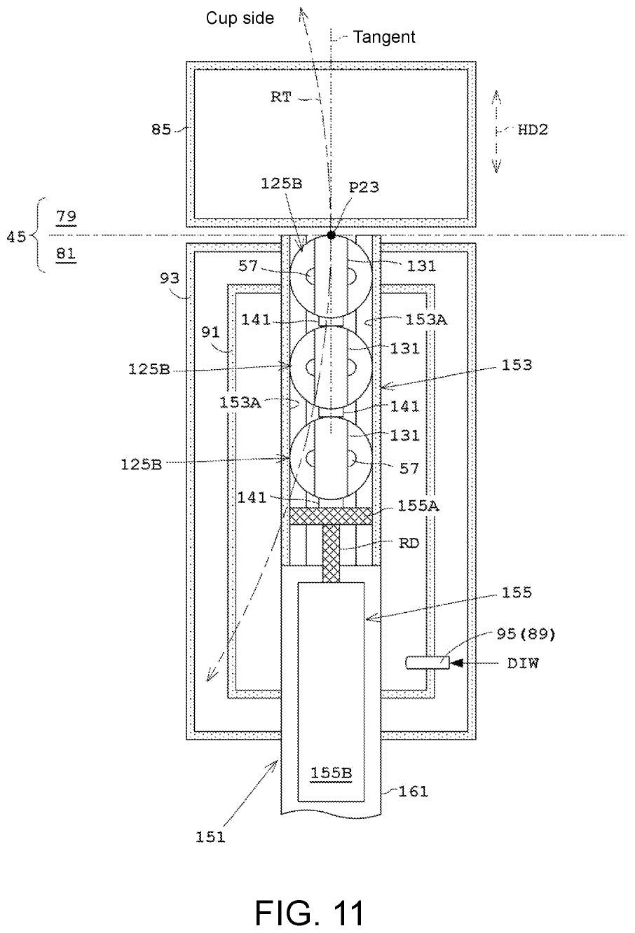

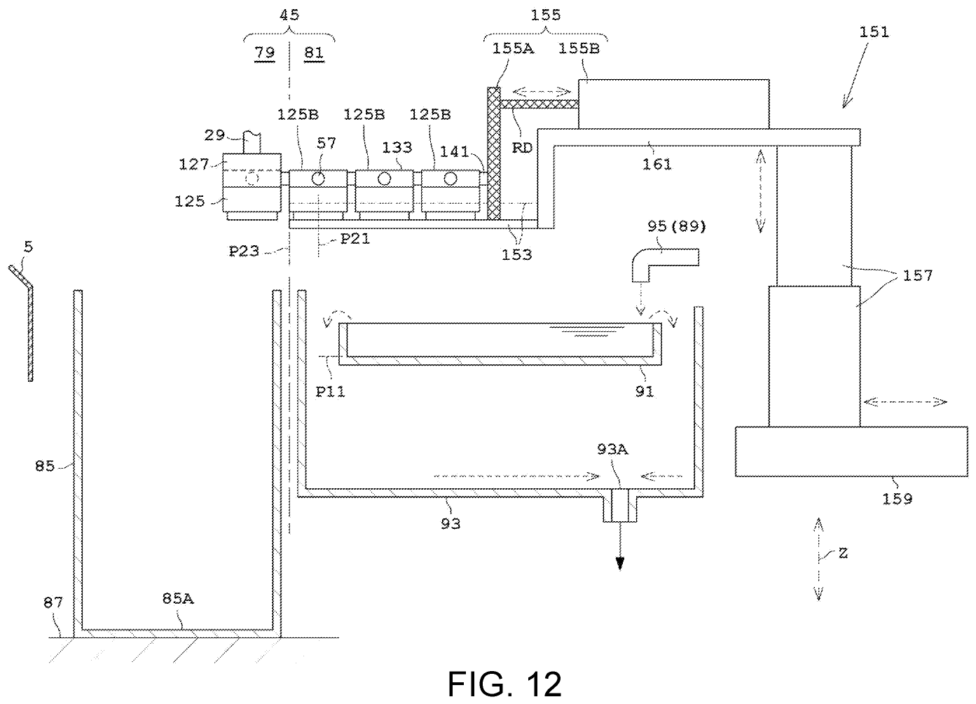

FIG. 11 is a plan view of the brush replacement part 45 according to Embodiment 3. FIG. 12 is a longitudinal cross-sectional view illustrating a schematic configuration of the brush replacement part 45 according to Embodiment 3.

Referring to FIGS. 11 and 12, firstly, the common grounds with Embodiment 1 are briefly described. The brush replacement part 45 includes the brush collection part 79 and the brush installation part 81. In addition, the brush collection part 79 includes the brush collection container 85. The brush installation part 81 stores one or multiple (e.g., 3) unused brushes 125B. The unused brush 125B is configured to be the same as the brush 125. The brush installation part 81 includes the liquid supply part 89, the brush accommodation container 91 and the liquid discharge container 93.

Then, the difference from Embodiment 1 is described. The brush installation part 81 includes a brush movement mechanism 151. The brush movement mechanism 151 includes a brush placement part 153, a pusher 155, a lifting part 157, and a horizontal movement part (linear actuator) 159.

The brush placement part 153 is configured to extend in a horizontal direction HD2 set in advance. In the brush placement part 153, three unused brushes 125B are placed in a row along the horizontal direction HD2. Two sidewalls 153A of the brush placement part 153 extending in the horizontal direction HD2 guide the three unused brushes 125B along the horizontal direction HD2. Each of the unused brushes 125B is provided so that the longitudinal direction of the guide 131 is parallel to the horizontal direction HD2.

In a plan view, when the tip end of the brush placement part 153 is located on the movement path RT of the brush 125, the brush placement part 153 is provided so that the horizontal direction D2 extends in a tangent direction.

The pusher 155 includes a pushing member 155A and a horizontal movement part (linear actuator) 155B. The horizontal movement part 155B includes a rod RD and further includes an electric motor or an air cylinder. The pushing member 155A is provided at the tip end of the rod RD. The horizontal movement part 155B moves the pushing member 155A forward and backward along the horizontal direction HD2. Accordingly, by pushing the three unused brushes 125B, the pusher 155 moves the first unused brush 125B to a replacement position P21.

The lifting part 157 lifts and lowers the brush placement part 153 and the pusher 155. The arm 161 connects the brush placement part 153 and the lifting part 157. Accordingly, the lifting part 157 can immerse the three unused brushes 125B placed in the brush placement part 153 into pure water stored in the brush accommodation container 91 or can draw the unused brushes 125B from the pure water. The pusher 155 is provided on the arm 161.

The horizontal movement part 159 moves the brush placement part 153, the pusher 155, and the lifting part 157 forward and backward along the horizontal direction HD2. The horizontal movement part 159 locates the tip end of the brush placement part 153 at a boundary position P23 between the brush collection part 79 and the brush installation part 81. Each of the lifting part 157 and the horizontal movement part 159 includes an electric motor or an air cylinder.

### (8) Brush Replacement

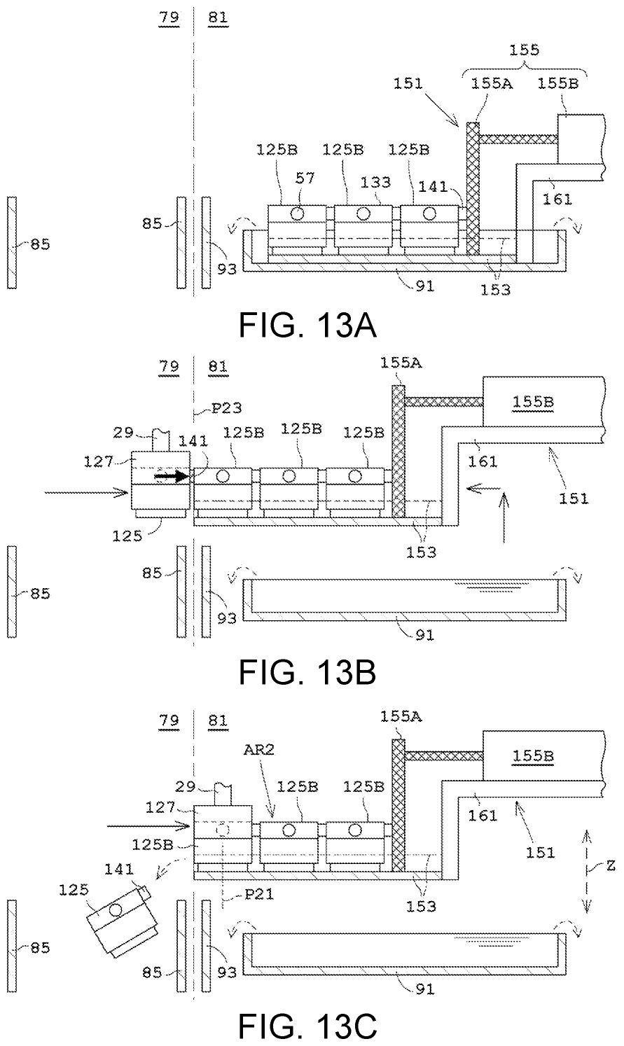

In the following, brush replacement is described. Referring to FIG. 13A, the three unused brushes 125B placed on the brush placement part 153 are immersed into the pure water stored in the brush accommodation container 91. The liquid nozzle 95 (see FIG. 12) keeps discharging pure water into the brush accommodation container 91.

Referring to FIG. 13B, by lifting the brush placement part 153, the lifting part 157 (see FIG. 12) of the brush movement mechanism 151 draws the three unused brushes 125B from the pure water. Then, the horizontal movement part 159 of the brush movement mechanism 151 moves the brush placement part 153 forward to locate the tip end of the brush placement part 153 at the boundary position P23.

Meanwhile, the brush mechanism 9 moves the brush 125 held by the brush holding part 127 to be adjacent to the first unused brush 125B from the standby pot 43 (see FIG. 2) At this time, the brush 125 is located so that the guide 131 of the first unused brush 125B is located on the extension line of the guide 131 of the brush 125.

Then, the brush mechanism 9 presses the button 141 of the brush 125 against the outer peripheral surface of the first unused brush 125B In this way, the button 141 of the brush 125 is pressed, and the two steel balls 57 (see FIG. 10B) of the brush 125 retreat toward the inner sides of the two opening parts 133. Thus, the brush 125 is movable along the groove part 149 of the brush holding part 127. Then, the brush mechanism 9 moves horizontally the brush holding part 127 along the guide 131 of each of the first unused brush part 125B and the brush 125.

Referring to FIG. 13C, when the brush 125 is removed from the groove part 149 of the brush holding part 127, the brush 125 is dropped and collected, as the used brush, 125 in the brush collection container 85. When the brush holding part 127 moves along the guide 131 of the first unused brush 125B, the button 141 of the first unused brush 125B contacts the outer peripheral surface of the unused brush 125B adjacent to the first unused brush 125B. However, the button 141 of the first unused brush 125B is not pressed. Thus, by accommodating the two steel balls 57 of the first unused brush 125B in the two recesses 147 of the brush holding part 147, the movement of the first unused brush 125B in the horizontal direction HD2 is limited. That is, the first unused brush 125B is installed to the brush holding part 127. Then, the unused brush 125B installed to the brush holding part 127 performs a process of removing initial contamination and then performs a process of cleaning the back surface of the substrate W.

After the first unused brush 125B is installed to the brush holding part 127, the unused brush 125B indicated by an arrow sign AR2 is moved to the replacement position P21 by the pusher 155. In the case where brush replacement is not carried out, the brush movement mechanism 151 immerses the unused brushes 125B placed in the brush placement part 153 into the pure water stored in the brush accommodation container 91.

According to the embodiment, the brush 125 includes the guide 131 extending in the horizontal direction HD1 set in advance. The brush holding part 127 includes the guide holding part 145 holding the guide 131 to be movable in the horizontal direction HD1. Thus, the movement of the brush 125 in the upper-lower direction and the rotation direction with respect to the brush holding part 127 can be limited. In addition, by accommodating the two steel balls 57 in the two recesses 147, the movement in the horizontal direction HD 1 can also be limited. Thus, the brush 125 can be prevented from falling off from the brush holding part 127.

In the embodiment, the three unused brushes 125B are provided linearly into a row along the horizontal direction HD2. Regarding this point, the three unused brushes 125B may also be provided in an arc shape along the movement path RT that is in an arc shape when viewed in a plan view. In such case, the guide 131 and the groove part 149 may also be formed to extend in an arc shape along the arc-shaped movement path RT when viewed in a plane view.

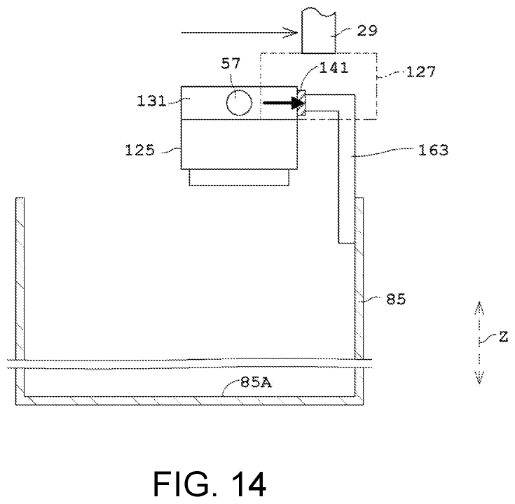

In addition, in the embodiment, as shown in FIG. 13B, when the brush 125 is to be removed from the brush holding part 127, the button 141 of the brush 125 is pressed against the outer peripheral surface of the first unused brush 125B. Regarding this point, as shown in FIG. 14, in order to prevent the first unused brush 125B from contacting the used brush 125A (brush 125) having been used, the brush collection part 79 may also include a removal member 163 located above the brush collection container 85 and provided for removing the brush 125.

In the case of such modified example, the brush mechanism 9 as shown in FIG. 14 presses the button 141 of the brush 125 against the removal member 163 to release the limitation (locking) and causes the brush 125 to slide. Accordingly, the brush 125 is removed from the brush holding part 127. Then, the brush mechanism 9 moves the brush holding part 127 to the first unused brush 125B and installs the first unused brush 125B to the brush holding part 127. In the case of the modified embodiment, it may also be that the horizontal movement part 159 of the brush movement mechanism 151 is omitted.

In addition, in the embodiment, it may also be that the brush accommodation container 91 is omitted, and mist-like pure water is directly sprayed from the liquid nozzle 95 onto the three unused brushes 125B. In addition, in the embodiment, the respective numbers of the steel balls 57 and the recesses 147 are not limited to two. For example, the respective numbers of the steel balls 57 and the recesses 147 may also be one. In addition, for example, it may also be that one steel ball 57 and one recess 147 are provided on the upper surface of the guide 131 and the bottom surface (the surface of the width WD2) of the groove part 149 facing the aforementioned upper surface.

The invention is not limited to the above embodiment, and modifications as follows can be made.

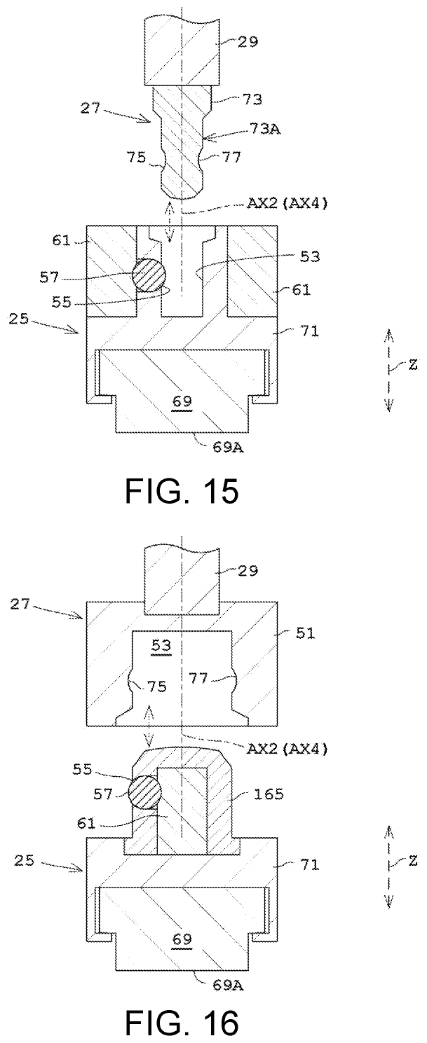

(1) In Embodiment 1, the brush holding part 27 includes three steel balls 57, the biasing part 61, etc., and the brush 25 includes the cylindrically columnar part 73. Regarding this point, as shown in FIG. 15, it may also be that the brush holding part 27 includes the cylindrically columnar part 73 having the recess 75 and the longitudinal recess 77. In addition, the brush 25 may also include three steel balls 57 and the biasing part 61.

Detailed description is as follows. The brush 25 includes: the brush body 69, having the cleaning surface 69A for cleaning the substrate W; the brush support part 71, supporting the brush body 69 from a side opposite to the cleaning surface 69A; the hole part 53, formed in a cylindrically columnar shape along a central axis (the vertical axis AX4) extending vertically; the three opening parts 55, provided on the sidewall 53A on the inner side of the hole part 53 and provided about the central axis; and three steel balls 57, respectively protruding from the three opening parts 55 toward the hole part 53. The three steel balls 57 are supported by the biasing part 61.

The brush holding part 27 includes: the cylindrically columnar part 73 that is protruding; and the recess 75 and the longitudinal recess 77 provided on the sidewall 73A of the cylindrically columnar wall 73 and about the vertical axis AX2 of the cylindrically columnar part 73. The longitudinal recess 77 is recessed longitudinally in the circumferential direction. In the case where the cylindrically columnar part 73 is inserted into the hole part 53 of the brush 25, the recess 75 accommodates one of the three steel balls 57, and the longitudinal recess 77 accommodates the remaining two steel balls 57 at the two ends thereof.

In addition, as shown in FIG. 16, a cylindrically columnar part 165 of the brush 25 may also include three steel balls 57 and the biasing part 61. In addition, it may also be that the hole part 53 of the brush holding part 27 includes the recess 75 and the longitudinal recess 77. The recess 75 accommodates one of the three steel balls 75. In addition, the longitudinal recess 77 accommodates the remaining two steel balls 57 at the two ends thereof.

The brush 25 may also include the hole part 53 (having the recess 75 and the longitudinal recess 77) as shown in FIG. 16. Comparatively, the brush holding part 27 may also include the cylindrically columnar part 165 (having the three steel balls 57 and the biasing part 61, etc.) as shown in FIG. 16.

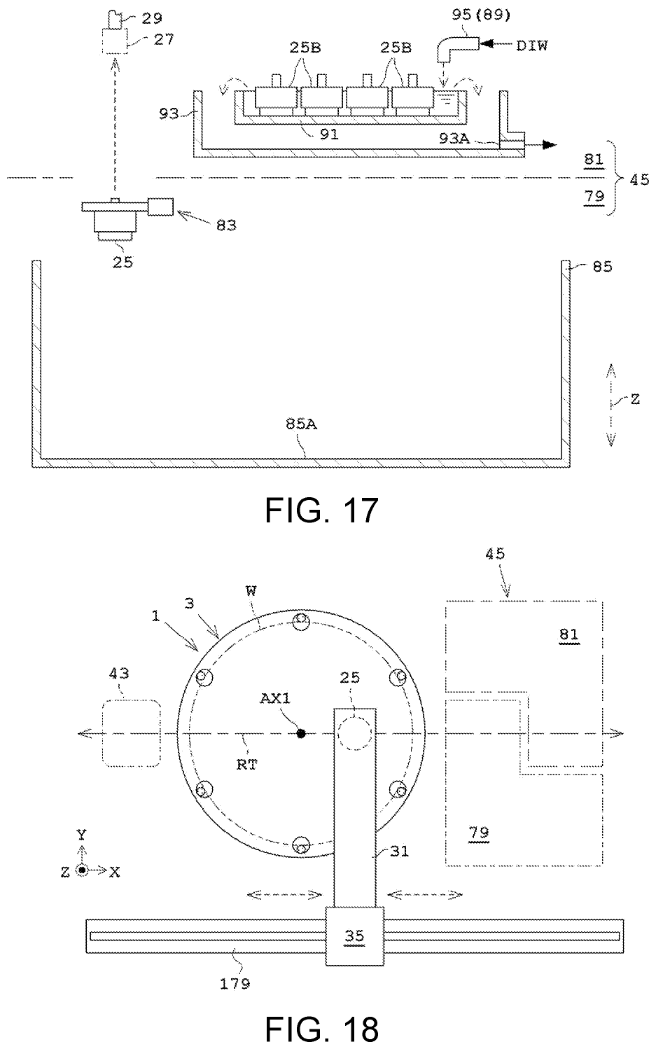

(2) In the respective embodiments and Modified Example (1), the brush collection part 79 and the brush installation part 81 are provided laterally. However, the invention is not limited thereto. For example, as shown in FIG. 17, the brush installation part 81 may also be provided above the brush collection part 79. Also, when viewed in a plan view, the brush installation part 81 may also repeat a portion or the entirety of the brush collection part 79. In the embodiment, the respective bottom surfaces (bottom walls) and sidewalls of the brush accommodation container 91 and the liquid discharge container 93 of the brush installation part 81 are equivalent to the separation part of the invention.

(3) In the respective embodiments and the respective modified examples, the brush mechanism 9 revolves the brush 25 (125) and the brush holding part 27 (127) to revolve about the vertical axis AX3. Regarding this point, as shown in FIG. 18, the brush mechanism 9 may also include a horizontal movement part (linear actuator) 179 linearly moving the brush 25 (125) and the brush holding part 27 (127). The horizontal movement part 179 includes an electric motor. In addition, the brush mechanism 9 may also include two horizontal movement parts 179 to move the brush 25 etc., in XY directions. The horizontal movement part 179 is equivalent to the brush movement mechanism of the invention.

(4) In Embodiment 1 and the respective modified examples, the brush accommodation container 91 are provided to be more distant with respect to the holding and rotating part 3 and the cup 5 than the removal member 83. Regarding this point, it may also be that the brush accommodation container 91 is provided to be closer with respect to the holding and rotating part 3 and the cup 5 than the removal member 83. That is, it may also be that the holding and rotating part 3, the brush accommodation container 91, and the removal member 83 (brush collection container 85) are provided in order.

(5) In the respective embodiments and the respective modified examples, the brush replacement part 45 is provided on a side opposite to the standby pot 43 via the holding and rotating part 3. Regarding this point, the brush replacement part 45 may also be provided on the side of the standby pot 43. For example, the standby pot 43 may also be provided between the brush replacement part 45 and the holding and rotating part 3.

(6) In the respective embodiments and the respective modified examples, each steel ball 57 as a protrusion part is a spherical body. However, the invention is not limited thereto. For example, the steel ball 57 may be in a shape of a semi-spherical body, a circularly columnar body, or a polygonal body.

(7) In the respective embodiments and the respective modified examples, the brush body 69 is formed by a PVA sponge brush. However, the invention is not limited thereto. The brush body 69 may also be formed by a resin body of PVA, for example, in which abrasive grains of silicon carbide (SiC), cerium oxide (CeO₂), silica (SiO₂), or diamond are dispersed.

(8) In the respective embodiments and the respective modified examples, the brush installation part 81 includes the liquid supply part 89 so that the brush body 69 is not dried. In the case where liquid (e.g., pure water) supply is not required, the liquid supply part 89 may also be omitted from the brush installation part 81.

(9) In the respective embodiments and the respective modified examples, for example, the separation part of the invention is a portion of the brush collection container 85. However, the separation part is not limited to be a portion of the container. For example, a separation wall (e.g., having a plate shape) may also be provided as the separation part between the brush collection part 79 and the brush installation part 81. In addition, it may also be configured that the separation wall and the upper end of at least one of the separation walls W1, W2, W3 is higher than the removal member 83.

(10) In the respective embodiments and the respective modified examples, the brush installation part 81 includes the brush accommodation container 91 and the liquid discharge container 93. However, where necessary, it may also be that the liquid discharge container 93 is omitted from the brush installation part 81. In this case, for example, it may also be that the brush accommodation container 91 includes the discharge port 93A that discharges pure water.

What is claimed is:

1. A substrate processing device, cleaning a substrate by using a brush, the substrate processing device comprising:
a substrate holding part, holding the substrate in a horizontal posture;
a brush, cleaning the substrate held by the substrate holding part;
a brush holding part, detachably holding the brush;
an arm, in which the brush holding part is provided at a tip end;
a brush collection part, collecting the brush from the brush holding part;
a brush installation part, storing the brush, which is an unused brush, and installing the unused brush that is stored to the brush holding part; and
a brush movement mechanism, moving, via the arm, the brush among a processing position on the substrate held by the substrate holding part, the brush collection part, and the brush installation part.

2. The substrate processing device as claimed in claim 1, wherein the brush installation part comprises a brush accommodation container accommodating the unused brush in storage.

3. The substrate processing device as claimed in claim 2, further comprising:
a liquid supply part, supplying a liquid to the brush accommodation container,
wherein the brush accommodation container immerses the unused brush into the liquid that is stored and stores the unused brush.

4. The substrate processing device as claimed in claim 3, wherein the brush installation part further comprises a horizontal movement part that horizontally moves the brush accommodation container.

5. The substrate processing device as claimed in claim 1, wherein the brush collection part comprises a brush collection container that collects the brush, which is a brush that has been used and removed.

6. The substrate processing device as claimed in claim 1, wherein the brush collection part comprises a removal member for removing the brush.

7. The substrate processing device as claimed in claim 1, wherein the brush installation part is provided to be adjacent to the brush collection part.

8. The substrate processing device as claimed in claim 1, further comprising a separation part, provided between the brush collection part and the brush installation part and separating the brush collection part and the brush installation part.

9. The substrate processing device as claimed in claim 1, wherein the brush holding part comprises:
a hole part, formed in a cylindrically columnar shape along a central axis extending vertically;
three opening parts, provided on a sidewall on an inner side of the hole part and provided about the central axis;
three protrusion parts, respectively protruding from the three opening parts toward the hole part; and
a biasing part, provided on an outer side of the three protrusion parts, and biasing the three protrusion parts in a direction of the central axis,
wherein the brush comprises:
a brush body, having a cleaning surface for cleaning the substrate;
a brush support part, supporting the brush body from a side opposite to the cleaning surface;
a cylindrically columnar part, protruding from the brush support part toward the side opposite to the cleaning surface; and
a recess and a longitudinal recess, provided on a sidewall of the cylindrically columnar part and about an axis of the cylindrically columnar part,
wherein the longitudinal recess is recessed longitudinally in a circumferential direction; and
in a case where the cylindrically columnar part is inserted into the hole part of the brush holding part, the recess accommodates one of the three protrusion parts, and the longitudinal recess accommodates at least one of remaining two protrusion parts.

10. The substrate processing device as claimed in claim 1,
wherein the brush comprises:
a brush body, having a cleaning surface for cleaning the substrate; and
a brush support part, supporting the brush body from a side opposite to the cleaning surface,
wherein the brush support part comprises:
a guide, extending in a horizontal direction set in advance on the side opposite to the cleaning surface;
an opening part, provided at the guide;
a protrusion part, protruding outward from the opening part;
a button part, provided on an outer peripheral surface of the brush support part; and
a protrusion width adjustment mechanism, adjusting a protrusion width of the protrusion part according to a pressing amount of the button part,
wherein the brush holding part comprises:
a guide holding part, holding the guide to be movable in the horizontal direction; and
a recess, provided at the guide holding part to accommodate the protrusion part,
in a case where the button part is pressed, the protrusion width adjustment mechanism makes the protrusion part retreat inwardly from the opening part, thereby allowing the brush to be able to move in the horizontal direction with respect to the brush holding part, and
in a case where the button part is not pressed, the protrusion width adjustment mechanism makes the protrusion part protrude outward from the opening part, thereby allowing to accommodate the protrusion part in the recess and limit a movement of the brush in the horizontal direction.
